(19) United States
(12) Patent Application Publication
(10) Pub. No.: US 2024/0195149 A1
(43) Pub. Date: Jun. 13, 2024

(54) LASER

(71) Applicant: ROCKLEY PHOTONICS LIMITED, Altrincham (GB)

(72) Inventor: Frank PETERS, Cork (IE)

(21) Appl. No.: 18/504,097

(22) Filed: Nov. 7, 2023

Related U.S. Application Data
(60) Provisional application No. 63/382,786, filed on Nov. 8, 2022.

(51) Int. Cl. H01S 5/10

(52) U.S. Cl. CPC H01S 5/1082; H01S 5/1039; H01S 5/1096

(57) ABSTRACT

A system including a laser. In some embodiments, the system includes a semiconductor laser, configured to generate laser light at an operating wavelength. The semiconductor laser may include: an optical waveguide including a gain medium; a first facet, at a first end of the optical waveguide; a second facet, at a second end of the optical waveguide; and a first reflector, in the optical waveguide, between the first facet and the second facet. The first reflector may be a discrete reflector.

### CROSS-REFERENCE TO RELATED APPLICATION(S)

The present application claims priority to and the benefit of U.S. Provisional Application No. 63/382,786, filed Nov. 8, 2022, entitled “DISCRETE MODE LASER”, the entire content of which is incorporated herein by reference.

### FIELD

One or more aspects of embodiments according to the present disclosure relate to semiconductor lasers, and more particularly to a semiconductor laser including a plurality of Fabry-Perot resonators.

### BACKGROUND

Semiconductor lasers may include a gain medium having a grain profile, and a laser resonator, having a plurality of resonant modes. The gain profile and the resonators may together determine the wavelength or wavelengths at which the laser produces laser light.

It is with respect to this general technical environment that aspects of the present disclosure are related.

### SUMMARY

According to an embodiment of the present disclosure, there is provided a system, including: a semiconductor laser, configured to generate laser light at an operating wavelength, the semiconductor laser including: an optical waveguide including a gain medium; a first facet, at a first end of the optical waveguide; a second facet, at a second end of the optical waveguide; and a first reflector, in the optical waveguide, between the first facet and the second facet, the first reflector being a discrete reflector.

In some embodiments: wherein the first reflector is a slot extending partially through the optical waveguide.

In some embodiments, the slot is filled with a transparent solid substance.

In some embodiments, the transparent solid substance has an index of refraction greater than an index of refraction of the optical waveguide.

In some embodiments, the transparent solid substance has an index of refraction less than an index of refraction of the optical waveguide.

In some embodiments, the first facet is not at a chip edge and the second facet is not at a chip edge.

In some embodiments: the semiconductor laser includes at least four reflectors including the first reflector, the first facet, and the second facet; and each pair of reflectors forming a resonator of a plurality of resonators.

In some embodiments, a gain bandwidth of the gain medium is less than five times the free spectral range of the shortest resonator of the resonators.

In some embodiments, a gain bandwidth of the gain medium is less than five times a free spectral range corresponding to a difference between an effective length of a first resonator of the resonators and an effective length of a second resonator of the resonators.

In some embodiments, the separation between the first facet and the second facet is an integer multiple of one-half of the operating wavelength.

In some embodiments, the separation between the first reflector and the first facet is an integer multiple of one-half of the operating wavelength.

In some embodiments, each of the resonators has an effective length that is an integer multiple of one-half of the operating wavelength.

In some embodiments, each reflector between the first facet and the second facet has an effective length that is an integer multiple of one-half of the operating wavelength.

In some embodiments, the semiconductor laser includes at most ten reflectors including the first reflector, the first facet, and the second facet.

In some embodiments, the semiconductor laser includes exactly eight reflectors including the first reflector, the first facet, and the second facet.

In some embodiments, the operating wavelength is between 350 nm and 2500 nm.

According to an embodiment of the present disclosure, there is provided a system, including: a semiconductor laser, configured to generate laser light at an operating wavelength, the semiconductor laser including: an optical waveguide including a gain medium; a first lithographically fabricated facet, at a first end of the optical waveguide; a second lithographically fabricated facet, at a second end of the optical waveguide; and a first lithographically fabricated reflector, in the optical waveguide, between the first lithographically fabricated facet and the second lithographically fabricated facet.

In some embodiments: the semiconductor laser includes at least four reflectors including the first lithographically fabricated reflector, the first lithographically fabricated facet, and the second lithographically fabricated facet; and each pair of reflectors forming a resonator of a plurality of resonators.

In some embodiments, the separation between the first lithographically fabricated facet and the lithographically fabricated second facet is an integer multiple of one-half of the operating wavelength.

In some embodiments, the separation between the first lithographically fabricated reflector and the first lithographically fabricated facet is an integer multiple of one-half of the operating wavelength.

### BRIEF DESCRIPTION OF THE DRAWINGS

These and other features and advantages of the present disclosure will be appreciated and understood with reference to the specification, claims, and appended drawings wherein:

FIG. 1 is a schematic drawing of a laser, according to an embodiment of the present disclosure;

FIG. 2 is a schematic drawing of a laser, according to an embodiment of the present disclosure;

FIG. 3 is a schematic drawing of a laser, according to an embodiment of the present disclosure;

FIG. 4 is a graph of S21\hat{ }2, according to an embodiment of the present disclosure; and

FIG. 5 is a performance graph, according to an embodiment of the present disclosure.

### DETAILED DESCRIPTION

The detailed description set forth below in connection with the appended drawings is intended as a description of exemplary embodiments of a laser provided in accordance with the present disclosure and is not intended to represent the only forms in which the present disclosure may be constructed or utilized. The description sets forth the features of the present disclosure in connection with the illustrated embodiments. It is to be understood, however, that the same or equivalent functions and structures may be accomplished by different embodiments that are also intended to be encompassed within the scope of the disclosure. As denoted elsewhere herein, like element numbers are intended to indicate like elements or features.

Single mode semiconductor lasers may be employed in various applications. Some single mode laser designs include a laser resonator formed by two facets that are formed by cleaving, and for which the phase of the reflection from the facet may be poorly controlled because of relatively low precision with which cleaves may be performed.

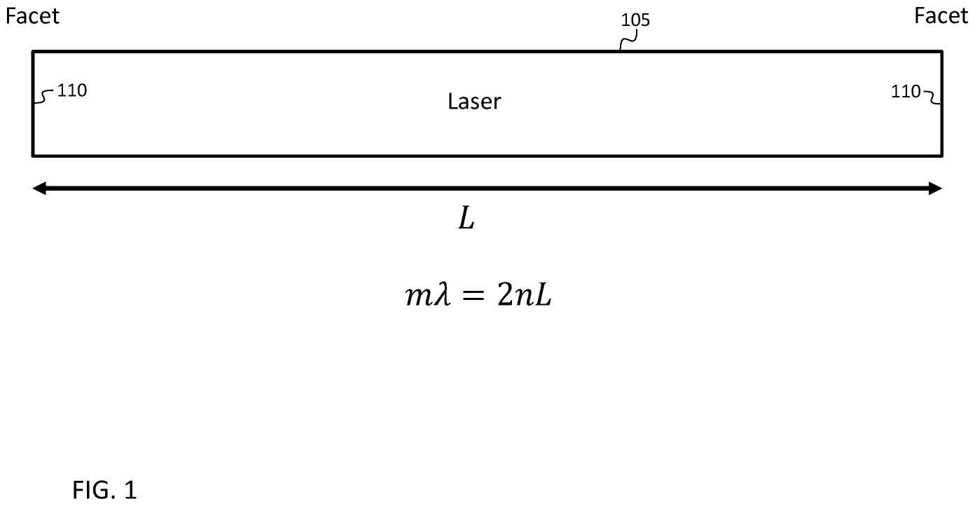

FIG. 1 shows a laser waveguide having a first facet at a first end of the waveguide and a second facet at a second of the waveguide. At a wavelength λ, the operating wavelength of the laser, it may be the case that mλ=2 nL, where m is an integer, L is the length of the resonator formed by the first facet 110 and the second facet 110, and n is the effective index of refraction. This constraint may be equivalent to the constraint that the effective length of the resonator (or the effective separation between the first facet 110 and the second facet 110) is equal to an integer multiple of half of the operating wavelength, where the effective length is defined as the length times the index of refraction (and the effective separation is defined as the separation times the index of refraction). One of the facets 110 may be a high reflector (e.g., as a result of a metal coating on the facet). Each of the first facet 110 and the second facet 110 may be formed by etching, using lithographic methods (e.g., using photolithography or e-beam lithography) part-way through the waveguide 105 (e.g., all the way through the waveguide 105) (e.g., from the top). Being fabricated in this manner may make it possible (i) to form each facet 110 so that it is set back from the chip edge and not at a chip edge (e.g., not formed by cleaving of the chip) and (ii) to control the phase of the reflection from the facet 110 more precisely than if it were fabricated by cleaving.

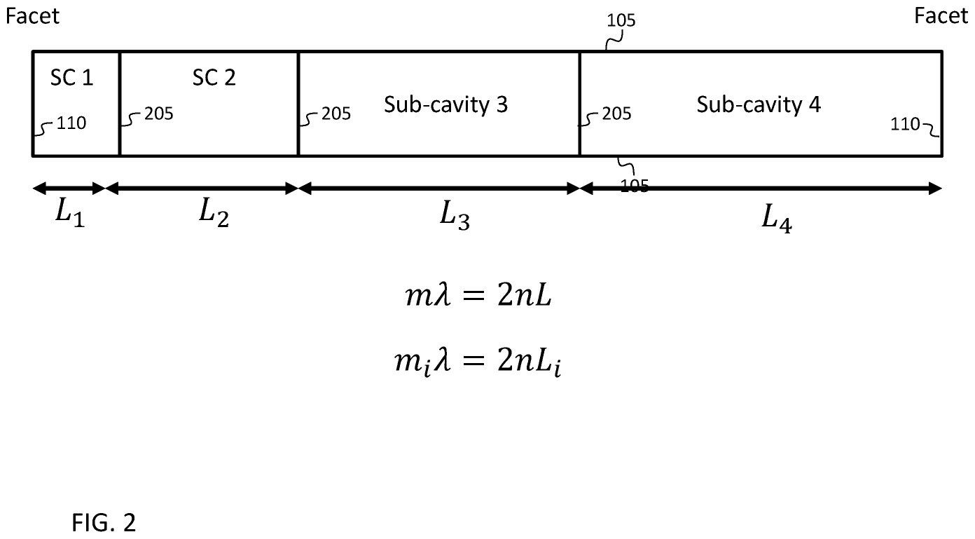

FIG. 2 shows a laser having two facets 110 (like the laser of FIG. 1) and also having three additional reflectors 205 (which may be referred to as internal reflectors 205 to distinguish them from the facets, which may also be reflectors). The additional reflectors may form additional resonators (or “cavities”) which may be referred to as sub-cavities (SC). The effective length of each of these cavities may also be selected to be equal to an integer multiple of half of the operating wavelength. For example, with i sub-cavities, it may be the case that mᵢλ=2nLᵢ. That is, each sub-cavity is resonant at the operating wavelength λ. This may increase the optical power resonating in each sub-cavity, making possible efficient extraction, in each sub-cavity, of optical power from the gain medium. The total length of the device (if the slots/defects have zero or negligible length) may therefore be given by (or approximately given by) L=ΣᵢLᵢ. This also means that the integer m=Σᵢmᵢ. Each of the reflectors may be a discrete reflector, as opposed to a distributed reflector such as a grating of a distributed feedback (DFB) laser.

Each integer mᵢ may represent a Fourier term for the laser cavity. The main integer m may be responsible for the Fabry Perot modes of the laser—that is the main resonant modes that could in principle be supported.

The free spectral range of the outer resonator (which is formed by the first facet 110 and the second facet 110) may be given by:

$$Δ f = \frac{c}{2 n L}$$

where c is the speed of light in vacuum.

For the sub cavities, each free spectral range may be given by:

$$Δ {f}_{i} = \frac{c}{2 n {L}_{i}} > Δ f$$

Thus, the sub-cavities may be resonant at only a subset of the Fabry-Perot modes. In some embodiments, all of the sub-cavities are resonant at the operating wavelength.

If the free spectral range of the shortest resonator of the resonators is N times the free spectral range of an outer resonator, then the separation, in frequency, between a first wavelength at which all of the sub-cavities are resonant and a nearest other wavelength at which all of the sub-cavities are resonant may be at least N times the free spectral range of the outer resonator. This separation may be chosen (by selection of the length of the shortest sub-cavity, or by selection of the lengths of several or all of the lengths of the sub-cavities, as discussed in further detail below) to be approximately equal to the gain bandwidth of the gain medium or greater than the gain bandwidth of the gain medium (e.g., it may be between 0.2 times the gain bandwidth of the gain medium and 5 times the gain bandwidth of the gain medium). The gain bandwidth of the gain medium may be defined as the separation (in frequency or wavelength) between (i) the first point below the gain peak at which the gain is 3 dB below the peak gain and (ii) the first point above the gain peak at which the gain is 3 dB below the peak gain. The arrangement of the sub-cavities may affect the behavior of the laser; for example, a laser that is otherwise the same as the laser of FIG. 2, but that has cavities of the same lengths arranged in a different order between the first facet 110 and the second facet 110, may have a behavior that is different from that of the laser of FIG. 2.

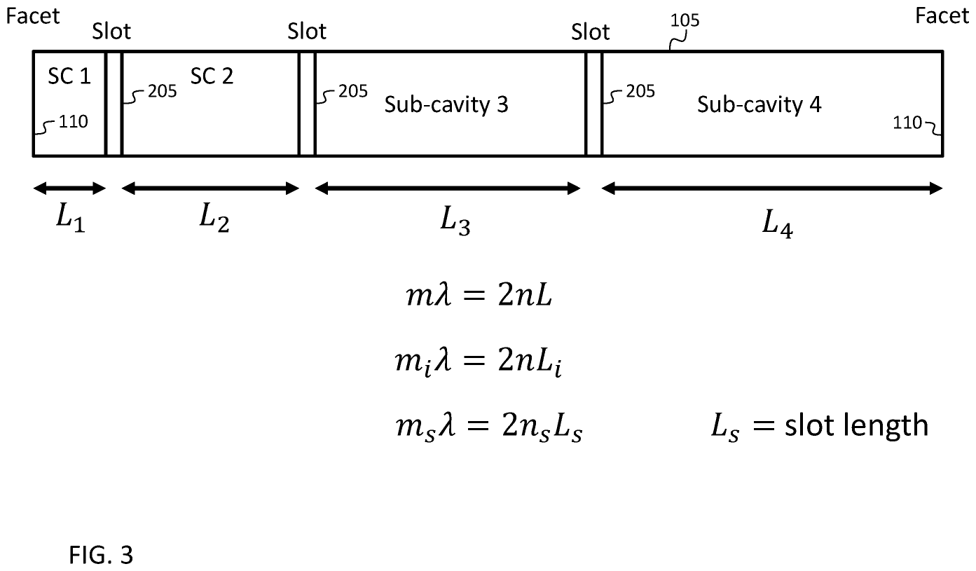

FIG. 3 shows a laser similar to that of FIG. 2, in which the length of each of the internal reflectors 205 (labeled “slots”) is shown explicitly. Each of the internal reflectors 205 may be a slot etched, using lithographic methods (e.g., using photolithography or e-beam lithography) part-way through the waveguide 105 (e.g., all the way through the waveguide 105) (e.g., from the top or from one side or from both sides). Each slot may be filled with a solid transparent material having a higher index of refraction than the waveguide 105, or having a lower index of refraction than the waveguide 105 (e.g., it may be composed of a top cladding material), or the slot may be empty (e.g., containing air or vacuum). In some embodiments, each of the internal reflectors 205 has an effective length that is an integer multiple of one-half of the operating wavelength, e.g.,

mₛλ=2nₛLₛ

where nₛ is the index of refraction of the material in the slot, Lₛ is the length of the slot and nₛLₛ is the effective length of the slot. Both the length of the slot and the effective length of the slot may be measured parallel to the direction of propagation of light, e.g., parallel to the waveguide 105.

In an embodiment such as that of FIG. 3 in which one or more of the resonators (e.g., the outer resonator) may have segments (e.g., the slots, and the portions of the waveguide 105 between the slots) containing materials with different indices of refraction, the effective length may be defined as the sum, over all of the segments, of a set of products, each of the products being the product of the length of a segment and the index of refraction of the segment. In some embodiments, the internal reflectors 205 are made relatively short, e.g., each has a length given by:

$${L}_{s} = \frac{λ}{2 {n}_{s}}$$

In some embodiments, the effective length of each slot is an integer multiple of one-half of the operating wavelength. In some embodiments, each slot is non-resonant and the effective length of each slot is one quarter of the operating wavelength plus an integer multiple of one-half of the operating wavelength.

A simulation may be used to search for sub-cavity lengths that result in good performance. The simulation may use transfer matrices based on the effects of propagation within the sub-cavities and within the slots, and based on the boundary conditions satisfied by the electromagnetic waves at each interface (e.g., at each end of each slot, and at the first facet 110 and the second facet 110). The search may be made to be exhaustive for each number of internal reflectors 205 by selecting the effective length of each of the sub-cavities to be an integer multiple of one half of the operating wavelength. These respective integers may then be changed in a systematic sequence until all combinations have been simulated. For example, if the outer resonator has an effective length of 100 times one half of the operating wavelength, and designs with four sub-cavities are being evaluated, then the integers tested (each integer being the ratio of (i) the effective length of a respective sub-cavity to (ii) one half of the operating wavelength) may include:

10, 20, 30, 60
20, 20, 20, 40
20, 30, 30, 20

This exhaustive testing of all possible sub-cavity effective lengths may be repeated for larger numbers of sub-cavities as desired. Various criteria may be employed to select the best design. For example, the design with the greatest side-mode suppression ratio (SMSR) (between adjacent wavelengths at which all of the sub-cavities are resonant) may be selected. In some embodiments, a design with 8 reflectors (6 internal reflectors 205, and the first facet 110 and the second facet 110) provides good performance. Significantly higher numbers of reflectors may result in loss that compromises performance, and significantly lower numbers of reflectors may degrade the SMSR, or the separation, in frequency, between a first wavelength at which all of the sub-cavities are resonant and a nearest other wavelength at which all of the sub-cavities are resonant.

In some embodiments the shortest sub-cavity may have an effective length of between 1.5 times the operating wavelength and 10 times the operating wavelength (e.g., it may be 5 times the operating wavelength).

In some embodiments, the separation, in frequency, between a first wavelength at which all of the sub-cavities are resonant and a nearest other wavelength at which all of the sub-cavities are resonant may be equal to m/k times the free spectral range of the outer resonator, where k is the greatest common divisor of the mᵢ. As such, selecting two of the mᵢ to be nearly equal may have a similar effect to that of making one of the sub-cavities much shorter than the outer resonator. For example, if a first sub-cavity has an effective length of 5 half-wavelengths (i.e., 5/2 of the operating wavelength) and a second sub-cavity has an effective length of 7 half-wavelengths, then the separation, in frequency, between a first wavelength at which all of the sub-cavities are resonant and a nearest other wavelength at which all of the sub-cavities are resonant may be equal to the free spectral range corresponding to 2 half-wavelengths (i.e., to the free spectral range corresponding to the difference between the effective length of the first sub-cavity (i.e., a first resonator) and the effective length of the second sub-cavity (i.e., a second resonator).

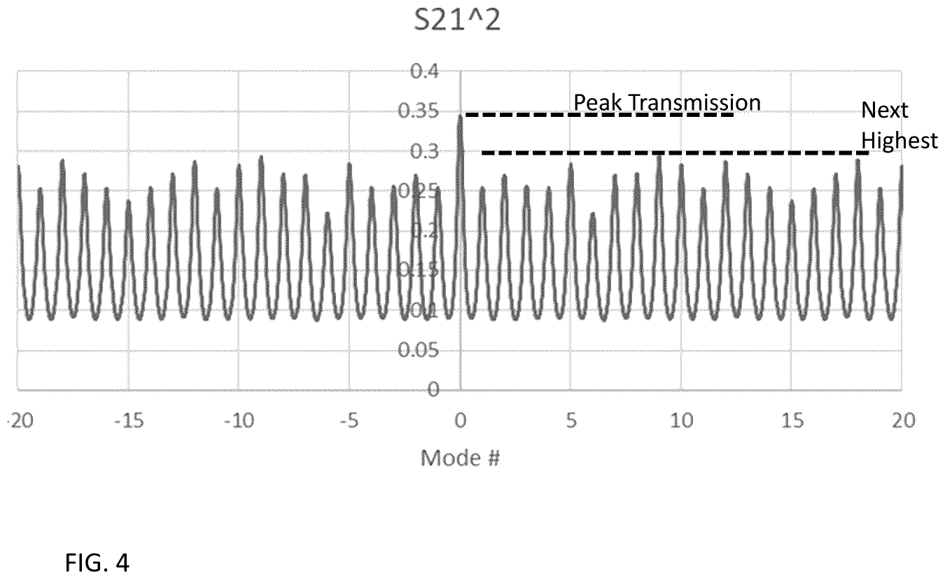

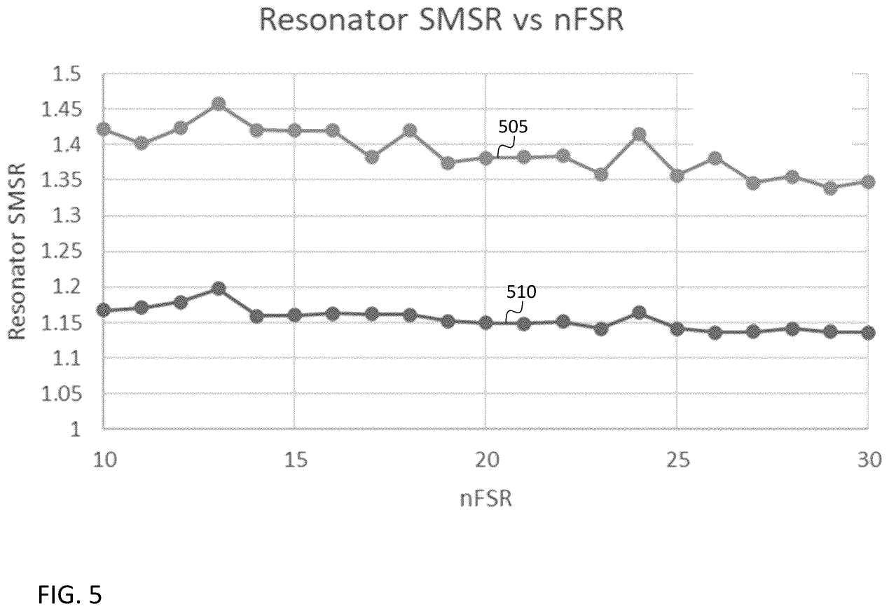

FIG. 4 is a graph of sub-threshold resonator round-trip gain, in some embodiments. It may be seen that the side-mode suppression ratio is about 0.05 dB. FIG. 5 shows simulated side-mode suppression ratio, as a function of nFSR (the ratio of (i) the separation, in frequency, between a first wavelength at which all of the sub-cavities are resonant and a nearest other wavelength at which all of the sub-cavities are resonant and (ii) the free spectral range of the outer resonator). Two curves are shown, including a first curve 505 showing ideal behavior and a second curve 510 showing “robust” behavior, e.g., the behavior that may be expected in the presence of fabrication errors of 0.1 microns (with, e.g., each end of each slot being over-etched by 0.1 microns, or each end of each slot being under-etched by 0.1 microns).

Two example designs, based on FIG. 5, where for the robust design criteria, there were local maxima at N=13 and N=24, include the following. Each design assumes one cleaved facet and one facet with a partial HR coating (50%). Each design is based on 6 slots, and therefore 7 sub-cavity lengths.

For each sub-cavity: mᵢλ=2nLᵢ, thus

$${L}_{i} = \frac{{m}_{i} λ}{2 n} .$$

For a laser of length ˜800 μm→m=Σmᵢ=3906

Example design values for mᵢ include:
N=13: mᵢ=600, 600, 600, 600, 600, 600, 300
N=24: mᵢ=486, 648, 648, 648, 648, 648, 162

The Fourier terms given by mᵢ may also be scaled according to the length of the laser cavity, since the optimization is independent of cavity length. That is, if all the Fourier terms—mᵢ were halved, this would correspond to a design, with similar performance characteristics, for a laser of length ˜400 μm.

In some embodiments, a laser as described herein is fabricated on a micro-transfer printing (MTP) coupon and the laser coupon is bonded to a platform wafer (e.g., using right-side-up or flip-chip bonding). The platform wafer may be a silicon photonic integrated circuit including passive filtering functions (e.g., wavelength combiners such as arrayed waveguide gratings or echelle gratings).

As used herein, the free spectral range of a resonator is the speed of light divided by twice the effective length of the resonator. Similarly, for any other effective length a free spectral range may be calculated in the same manner, and, for example, the free spectral range corresponding to a difference between an effective length of a first resonator and an effective length of a second resonator is equal to the speed of light divided by twice this difference.

As used herein, “partially” means “at least in part” and, as such, “partially” includes “wholly” as a special case. Similarly “part-way” includes “entirely” as a special case. As used herein, “a portion of” something means “at least some of” the thing, and as such may mean less than all of, or all of, the thing. As such, “a portion of” a thing includes the entire thing as a special case, i.e., the entire thing is an example of a portion of the thing. As used herein, when a second quantity is “within Y” of a first quantity X, it means that the second quantity is at least X-Y and the second quantity is at most X+Y. As used herein, when a second number is “within Y %” of a first number, it means that the second number is at least (1−Y/100) times the first number and the second number is at most (1+Y/100) times the first number. As used herein, the word “or” is inclusive, so that, for example, “A or B” means any one of (i) A, (ii) B, and (iii) A and B.

As used herein, when a method (e.g., an adjustment) or a first quantity (e.g., a first variable) is referred to as being “based on” a second quantity (e.g., a second variable) it means that the second quantity is an input to the method or influences the first quantity, e.g., the second quantity may be an input (e.g., the only input, or one of several inputs) to a function that calculates the first quantity, or the first quantity may be equal to the second quantity, or the first quantity may be the same as (e.g., stored at the same location or locations in memory as) the second quantity.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” or “between 1.0 and 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Similarly, a range described as “within 35% of 10” is intended to include all subranges between (and including) the recited minimum value of 6.5 (i.e., (1−35/100) times 10) and the recited maximum value of 13.5 (i.e., (1+35/100) times 10), that is, having a minimum value equal to or greater than 6.5 and a maximum value equal to or less than 13.5, such as, for example, 7.4 to 10.6. Any maximum numerical limitation recited herein is intended to include all lower numerical limitations subsumed therein and any minimum numerical limitation recited in this specification is intended to include all higher numerical limitations subsumed therein.

Although exemplary embodiments of a laser have been specifically described and illustrated herein, many modifications and variations will be apparent to those skilled in the art. Accordingly, it is to be understood that a laser constructed according to principles of this disclosure may be embodied other than as specifically described herein. The invention is also defined in the following claims, and equivalents thereof.

What is claimed is:

1. A system, comprising:
a semiconductor laser, configured to generate laser light at an operating wavelength,
the semiconductor laser comprising:
an optical waveguide comprising a gain medium;
a first facet, at a first end of the optical waveguide;
a second facet, at a second end of the optical waveguide; and
a first reflector, in the optical waveguide, between the first facet and the second facet, the first reflector being a discrete reflector.

2. The system of claim 1, wherein:
wherein the first reflector is a slot extending partially through the optical waveguide.

3. The system of claim 2, wherein the slot is filled with a transparent solid substance.

4. The system of claim 3, wherein the transparent solid substance has an index of refraction greater than an index of refraction of the optical waveguide.

5. The system of claim 3, wherein the transparent solid substance has an index of refraction less than an index of refraction of the optical waveguide.

6. The system of claim 1, wherein the first facet is not at a chip edge and the second facet is not at a chip edge.

7. The system of claim 1, wherein:
the semiconductor laser comprises at least four reflectors including the first reflector, the first facet, and the second facet; and
each pair of reflectors forming a resonator of a plurality of resonators.

8. The system of claim 7, wherein a gain bandwidth of the gain medium is less than five times the free spectral range of the shortest resonator of the resonators.

9. The system of claim 7, wherein a gain bandwidth of the gain medium is less than five times a free spectral range corresponding to a difference between an effective length of a first resonator of the resonators and an effective length of a second resonator of the resonators.

10. The system of claim 7, wherein the separation between the first facet and the second facet is an integer multiple of one-half of the operating wavelength.

11. The system of claim 10, wherein the separation between the first reflector and the first facet is an integer multiple of one-half of the operating wavelength.

12. The system of claim 7, wherein each of the resonators has an effective length that is an integer multiple of one-half of the operating wavelength.

13. The system of claim 7, wherein each reflector between the first facet and the second facet has an effective length that is an integer multiple of one-half of the operating wavelength.

14. The system of claim 1, wherein the semiconductor laser comprises at most ten reflectors including the first reflector, the first facet, and the second facet.

15. The system of claim 1, wherein the semiconductor laser comprises exactly eight reflectors including the first reflector, the first facet, and the second facet.

16. The system of claim 1, wherein the operating wavelength is between 350 nm and 2500 nm.

17. A system, comprising:
a semiconductor laser, configured to generate laser light at an operating wavelength,
the semiconductor laser comprising:
an optical waveguide comprising a gain medium;
a first lithographically fabricated facet, at a first end of the optical waveguide;
a second lithographically fabricated facet, at a second end of the optical waveguide; and
a first lithographically fabricated reflector, in the optical waveguide, between the first lithographically fabricated facet and the second lithographically fabricated facet.

18. The system of claim 17, wherein:
the semiconductor laser comprises at least four reflectors including the first lithographically fabricated reflector, the first lithographically fabricated facet, and the second lithographically fabricated facet; and
each pair of reflectors forming a resonator of a plurality of resonators.

19. The system of claim 18, wherein the separation between the first lithographically fabricated facet and the lithographically fabricated second facet is an integer multiple of one-half of the operating wavelength.

20. The system of claim 18, wherein the separation between the first lithographically fabricated reflector and the first lithographically fabricated facet is an integer multiple of one-half of the operating wavelength.
